(19) United States
(12) Patent Application Publication
(10) Pub. No.: US 2025/0249629 A1
(43) Pub. Date: Aug. 7, 2025

(54) METHOD OF MANUFACTURING SEMICONDUCTOR MODULE

(71) Applicant: FUJI ELECTRIC CO., LTD., Kawasaki-shi (JP)

(72) Inventors: Masaoki MIYAKOSHI, Matsumoto-city (JP); Rikihiro MARUYAMA, Matsumoto-city (JP)

(73) Assignee: FUJI ELECTRIC CO., LTD., Kawasaki-shi (JP)

(21) Appl. No.: 19/190,446

(22) Filed: Apr. 25, 2025

Related U.S. Application Data
(63) Continuation of application No. PCT/JP2024/014486, filed on Apr. 10, 2024.

(30) Foreign Application Priority Data
May 30, 2023 (JP) 2023-088901

(51) Int. Cl. B29C 45/26; B29L 31/34; H01L 21/56

(52) U.S. Cl. CPC B29C 45/2628; H01L 21/565; B29L 2031/3406

(57) ABSTRACT

A molding space includes a molding inner surface defining an outer frame and a housing region, a molding outer surface provided outside the molding inner surface and having injection ports, which communicate with the molding space, formed at positions inwardly separated from end portions, and a molding bottom surface that connects the molding inner surface and the molding outer surface and contacts a bottom surface of the outer frame. Mold pins are disposed perpendicular to the molding bottom surface at corners of the molding space in plan view. During injection, rod-shaped second mold components are positioned parallel to the mold pins between the mold pins and the injection ports in the molding space and closer to the molding inner surface than the molding outer surface in plan view.

### CROSS-REFERENCE TO RELATED APPLICATION

This application is a continuation application of International Application PCT/JP2024/014486 filed on Apr. 10, 2024, which designated the U.S., which claims priority to Japanese Patent Application 2023-088901, filed on May 30, 2023, the entire contents of which are incorporated herein by reference.

### BACKGROUND OF THE INVENTION

### 1. Field of the Invention

The embodiments discussed herein relate to a method of manufacturing a semiconductor module.

### 2. Background of the Related Art

A semiconductor module includes a case that houses a semiconductor element and a printed circuit board that is attached to an upper surface of the case using tapping screws. The case is made of resin and is formed with mounting holes for the tapping screws that are inserted through the printed circuit board. The mounting holes are cylindrical in their overall shape and have hemispherical front ends. By doing so, the formation of cracks and voids during resin molding of the case is suppressed (see, for example, International Publication Pamphlet No. WO 2021/024636).

A semiconductor device includes an insulating substrate on which a semiconductor chip is disposed, a heat dissipating plate on which the insulating substrate is disposed, and a resin case including screw holes that engage tapping screws that are inserted through through-holes in the heat dissipating plate. Gaps at the screw holes in the resin case that have been engaged by the tapping screws are filled with a high voltage-resistant resin, which improves the discharge withstand voltage and dielectric breakdown resistance (see, for example, Japanese Laid-open Patent Publication No. 2006-032392).

### SUMMARY OF THE INVENTION

According to an aspect, there is provided a method of manufacturing a semiconductor module, including: preparing a molding material and a molding die, the molding die including a first die component having a cavity corresponding to a shape of an exterior of a case and injection ports that communicate with the cavity from outside the first die component, the molding die further including rod-shaped mold pins for forming tubular fastening holes in the case, into which screws are to be fastened, the case being rectangular in a plan view of the semiconductor module, and having an outer frame that surrounds a housing region within the case, the fastening holes being disposed at respective corners of an upper surface of the outer frame; providing the mold pins inside the cavity of the first die component and injecting the molding material from the injection ports into the cavity, wherein the cavity of the first die component has a molding space for molding the outer frame, the molding space includes: a molding inner surface defining a boundary of the outer frame and the housing region; a molding outer surface provided outside the molding inner surface, the molding outer surface having the injection ports that communicate with the molding space, at positions away from a periphery of the molding outer surface; and a molding bottom surface connecting the molding inner surface to the molding outer surface so as to contact a lower surface of the outer frame, the mold pins are disposed vertically with respect to the molding bottom surface at respective corners of the molding space in the plan view, and the molding die further includes rod-shaped second die components, each second die component being disposed, during the injecting of the molding material, between one mold pin and one injection port that are adjacent to each other, so as to be parallel with the one mold pin and positioned closer to the molding inner surface than to the molding outer surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a perspective view of a semiconductor module according to a first embodiment;

FIG. 2 is a cross-sectional view of the semiconductor module according to the first embodiment;

FIG. 3 is a rear view of the semiconductor module according to the first embodiment;

FIG. 4 is a plan view of a semiconductor unit included in the semiconductor module according to the first embodiment;

FIG. 5 is a first cross-sectional view of a semiconductor module to which a printed circuit board according to the first embodiment has been attached;

FIG. 6 is a second cross-sectional view of a semiconductor module to which a printed circuit board according to the first embodiment has been attached;

FIG. 7 is an enlarged cross-sectional view of a semiconductor module to which a printed circuit board according to the first embodiment has been attached;

FIG. 8 is a flowchart depicting a method of manufacturing a case included in the semiconductor module according to the first embodiment;

FIG. 9 is a plan view of a molding apparatus according to the first embodiment;

FIG. 10 is a first cross-sectional view of a molding die included in the molding apparatus according to the first embodiment;

FIG. 11 is a second cross-sectional view of the molding die included in the molding apparatus according to the first embodiment;

FIG. 12 is a third cross-sectional view of the molding die included in the molding apparatus according to the first embodiment;

FIG. 13 is a first cross-sectional view depicting an injection step included in the method of manufacturing of a case according to a comparative example;

FIG. 14 is an enlarged cross-sectional view of a case according to the comparative example;

FIG. 15 is a perspective view of a semiconductor module according to a second embodiment;

FIG. 16 is a second cross-sectional view of a semiconductor module to which a printed circuit board according to the second embodiment has been attached;

FIG. 17 is an enlarged cross-sectional view of a semiconductor module to which the printed circuit board according to the second embodiment has been attached;

FIG. 18 is a plan view of a molding apparatus according to the second embodiment;

FIG. 19 is a second cross-sectional view of a molding die included in the molding apparatus according to the second embodiment; and

FIG. 20 is a third cross-sectional view of a molding die included in the molding apparatus according to the second embodiment.

### DETAILED DESCRIPTION OF THE INVENTION

Several embodiments will be described below with reference to the accompanying drawings. Note that in the present embodiments, the expressions “front surface” and “upper surface” refer to an X-Y plane that faces upward (the “+Z direction”) for the semiconductor module in the drawings. In the same way, the expression “upward” refers to the upward direction (the “+Z direction”) for the semiconductor module in the drawings. The expressions “rear surface” and “lower surface” refer to an X-Y plane that faces downward (the “−Z direction”) for the semiconductor module in the drawings. In the same way, the expression “downward” refers to the (the downward direction “−Z direction”) for the semiconductor module in the drawings. The same directions are referred to as needed in the other drawings. The expressions “front surface”, “upper surface”, “up”, “rear surface”, “lower surface”, “down”, and “side surface” are merely convenient expressions used to specify relative positional relationships and are not intended to limit the technical scope of the present disclosure. As one example, “up” and “down” do not necessarily mean directions that are perpendicular to the ground. That is, the “up” and “down” directions are not limited to the direction of gravity. The expression “main component” in the following description indicates a case where a component composes 80 vol % or higher. The expression “substantially the same” includes values within a range of +10%. The expressions “perpendicular” and “parallel” too may include directions within a range of +10%.

### First Embodiment

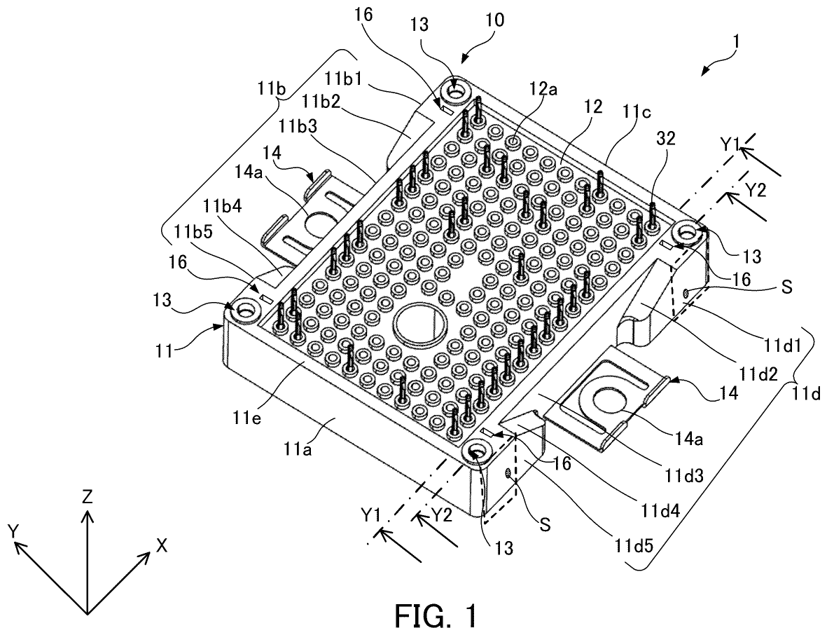

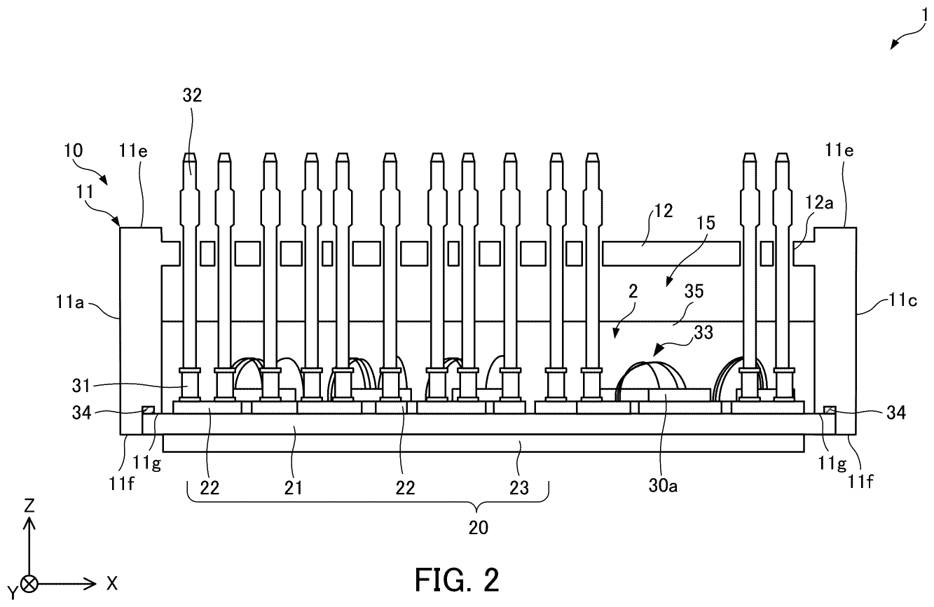

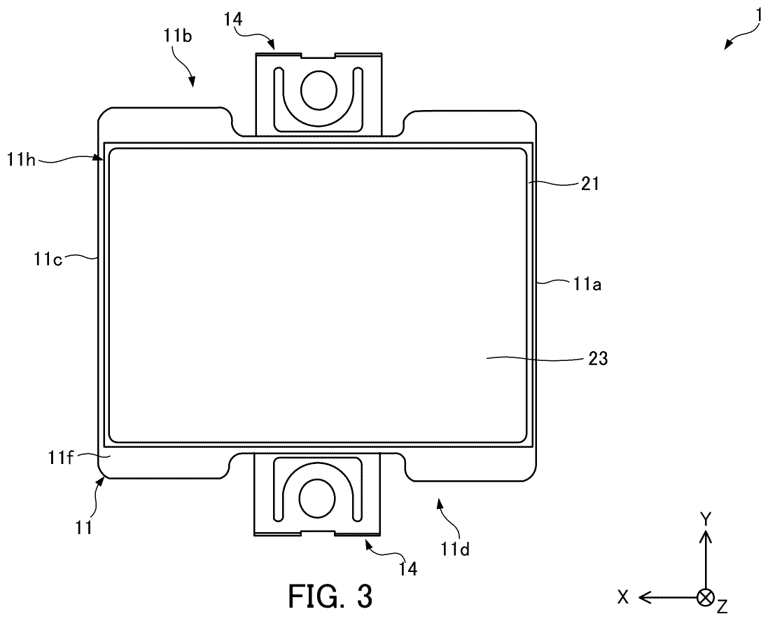

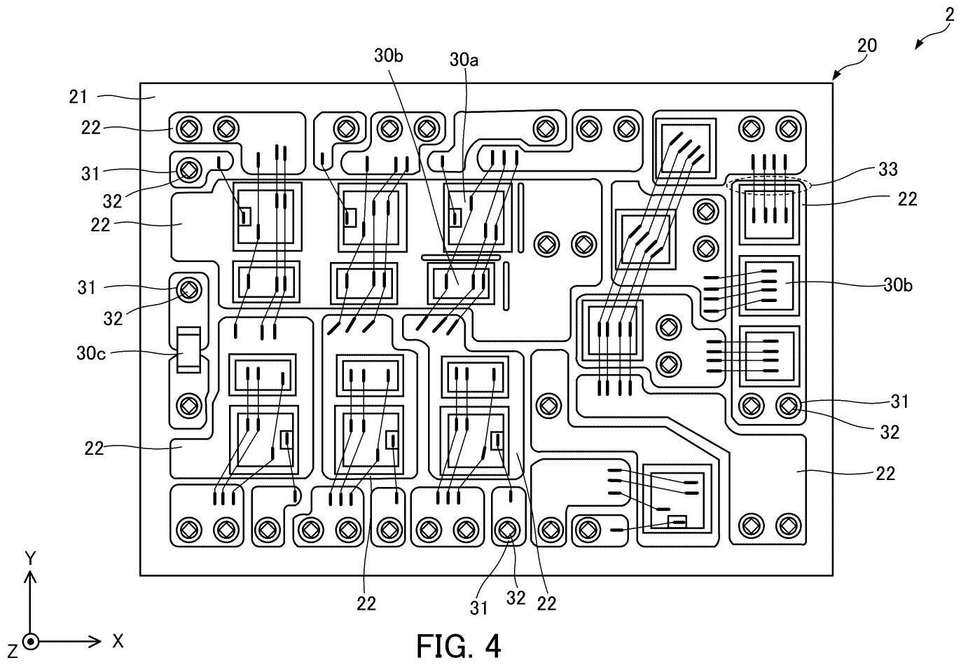

A semiconductor module according to a first embodiment will be described with reference to FIGS. 1 to 4. FIG. 1 is a perspective view of a semiconductor module according to the first embodiment, and FIG. 2 is a cross-sectional view of the semiconductor module according to the first embodiment. FIG. 3 is a rear view of the semiconductor module according to the first embodiment. FIG. 4 is a plan view of a semiconductor unit included in the semiconductor module according to the first embodiment. Note that FIG. 2 is a cross-sectional view taken along a dash-dotted line Y1-Y1 in FIG. 1. In the present embodiment, a plurality of conductive patterns 22, a plurality of semiconductor chips 30a and 30b, a plurality of contact components 31, a plurality of external connection terminals 32, and a plurality of wires 33 will be collectively referred to using the same reference numerals without distinguishing between individual elements.

The semiconductor module 1 includes a case 10 and a semiconductor unit 2 housed inside the case 10. The plurality of external connection terminals 32 included in the semiconductor unit 2 extend to the outside from a front surface of the case 10. The inside of the case 10 is encapsulated with an encapsulating member 35.

The case 10 includes an outer frame 11 that surrounds the components of a semiconductor module 1, described later, mounting portions 14 that are integrally attached to the outer frame 11, and a lid portion 12 that covers the upper part of the outer frame 11 and is integrally attached to the outer frame 11.

The outer frame 11 is shaped as a box that is substantially rectangular in plan view and has ring-shaped upper and lower surfaces 11e and 11f that are continuous. These upper and lower surfaces 11e and 11f are substantially parallel and substantially smooth. The outer frame 11 includes side walls 11a to 11d which surround a housing region 15 (see FIG. 2) on four sides in that order. The side walls 11a to 11d are integrally connected to form a continuous ring shape in plan view. The upper surface 11e and the lower surface 11f are formed by the side walls 11a to 11d which are integrally connected. The side walls 11a and 11c (second side wall and fourth side wall) correspond to the short sides of the outer frame 11 and are parallel to a “width direction” (or “+Y direction”) of the outer frame 11. The side walls 11b and 11d (first side wall and third side wall) correspond to the long sides of the outer frame 11 and are parallel to a length direction (or “+X directions”) of the outer frame 11.

The side wall 11b further includes outermost surfaces 11b1 and 11b5, an outer surface 11b3, and inclined surfaces 11b2 and 11b4. The outermost surfaces 11b1 and 11b5 are located further outside (in the +Y direction) than the outer surface 11b3. That is, in the side wall 11b, the outermost surfaces 11b1 and 11b5 are thicker than the outer surface 11b3. Note that these thicker parts (or “fastening parts” or “thicker portion”) include the fastening portions (fastening holes) 13, which will be described later. The outermost surfaces 11b1 and 11b5 also include gate marks S, not illustrated. These gate marks S will be described later.

The inclined surfaces 11b2 and 11b4 are provided along the length direction (the “+X direction”) in regions of the outermost surfaces 11b1 and 11b5 that protrude from the outer surface 11b3. In a side view, the inclined surfaces 11b2 and 11b4 are downwardly inclined from the upper surface 11e on the sides of the side wall 11c and 11a of the outer frame 11, described later, toward a center of the side wall 11b. The “fastening parts” are parts surrounded by the outermost surfaces 11b1 and 11b5, the inclined surfaces 11b2 and 11b4, the upper surface 11e, and the lower surface 11f.

The side wall 11d further includes outermost surfaces 11d1 and 11d5, an outer surface 11d3, and inclined surfaces 11d2 and 11d4. The outermost surfaces 11d1 and 11d5 are located further outside (in the −Y direction) than the outer surface 11d3. That is, in the side wall 11d, the outermost surfaces 11d1 and 11d5 are thicker than the outer surface 11d3. Note that these thicker parts (or “fastening parts”) include the fastening portions 13. The outermost surfaces 11d1 and 11d5 also include gate marks S. These gate marks S will be described later.

Note that the thicknesses of the side walls 11a and 11c are equal to or thinner than the thicknesses of the outer surfaces 11b3 and 11d3 of the side walls 11b and 11d, respectively. In other words, the thicknesses of the side walls 11a and 11c are thinner than the thicknesses of the outermost surfaces 11b1 and 11b5 and the outermost surfaces 11d1 and 11d5 of the side walls 11b and 11d, respectively.

The inclined surfaces 11d2 and 11d4 are provided along the length direction (the +X direction) in regions of the outermost surfaces 11d1 and 11d5 that protrude from the outer surface 11d3. In a side view, the inclined surfaces 11d2 and 11d4 are downwardly inclined from the upper surface 11e on the sides of the side wall 11c and 11a of the outer frame 11, described later, toward a center of the side wall 11d. The “fastening parts” are parts surrounded by the outermost surfaces 11d1 and 11d5, the inclined surfaces 11d2 and 11d4, the upper surface 11e, and the lower surface 11f.

Also, in plan view, the fastening portions 13 are formed together with columnar notches 16 on the upper surface 11e of the side walls 11b and 11d on the sides of the side walls 11a and 11c. Note that the fastening portions 13 and the columnar notches 16 will be described in detail later.

Each mounting portion 14 is integrally formed in central portions of the side walls 11b and 11d. The mounting portions 14 have shapes that approximate to flat plates and are formed so as to be flush with the lower surface 11f of the outer frame 11 (that is, the side walls 11b and 11d). Mounting holes 14a may be formed in the mounting portions 14. The mounting portions 14 may be made of metal, for example. The semiconductor module 1 is placed in a predetermined installation region, and screws are inserted through the mounting holes 14a of the mounting portions 14 to fasten the semiconductor module 1 at an installation position. By doing so, the semiconductor module 1 is fixed at the installation region.

The lid portion 12 covers the upper part of the housing region 15 and is integrally connected to each of the side walls 11a to 11d. The lid portion 12 does not need to be flush with the upper surface 11e of the side walls 11a to 11d and may be connected below the upper surface 11e. Terminal holes 12a may be formed in a grid pattern in the lid portion 12. The plurality of external connection terminals 32 are inserted through these terminal holes 12a in the lid portion 12 and extend vertically upward (that is, in the +Z direction) from the outer frame 11 toward the lid portion 12. Another opening aside from the terminal holes 12a may be formed in the lid portion 12. Such opening may have a larger diameter than the terminal holes 12a. The case 10 may be filled with the encapsulating member 35 through this opening.

The case 10 described above (aside from the mounting portions 14) may be made of a thermoplastic resin. Example resins include polyphenylene sulfide resin, polybutylene terephthalate resin, polybutylene succinate resin, polyamide resin, and acrylonitrile butadiene styrene resin. The case 10 is constructed to include the mounting portions 14 by injection molding using thermoplastic resin.

The semiconductor unit 2 includes an insulated circuit board 20, the semiconductor chips 30a and 30b, and the plurality of external connection terminals 32. The insulated circuit board 20 includes an insulating board 21, a plurality of conductive patterns 22, and a metal plate 23. The insulating board 21 and the metal plate 23 are rectangular in plan view. Corners of the insulating board 21 and the metal plate 23 may be chamfered into rounded or beveled shapes. In plan view, the metal plate 23 is smaller in size than the insulating board 21, and is formed inside the insulating board 21.

The insulating board 21 is made of a material that is electrically insulating and has superior thermal conductivity. This type of insulating board 21 may be made of ceramics. Example ceramics include aluminum oxide, aluminum nitride, and silicon nitride.

The plurality of conductive patterns 22 are formed on the front surface of the insulating board 21. The plurality of conductive patterns 22 are made of a metal with superior electrical conductivity. Example metals include copper, aluminum, and an alloy containing at least one of these metals as a main component. A plating process may be performed on the surfaces of the plurality of conductive patterns 22. When doing so, examples of the plating material used include nickel, nickel-phosphorus alloy, and nickel-boron alloy. Plating the plurality of conductive patterns 22 improves corrosion resistance.

The plurality of conductive patterns 22 are formed on the front surface of the insulating board 21 as follows. A metal plate is formed on the front surface of the insulating board 21, and the metal plate is subjected to a process such as etching to obtain the plurality of conductive patterns 22 in predetermined shapes. Alternatively, the plurality of conductive patterns 22 may be cut out in advance from a metal plate and pressure-bonded to the front surface of the insulating board 21. Note that the illustrated plurality of conductive patterns 22 are mere examples. The number, shapes, sizes, and positions of the conductive patterns 22 may be appropriately selected as needed.

The metal plate 23 is formed on the rear surface of the insulating board 21. The metal plate 23 is rectangular in shape. In plan view, the area of the metal plate 23 is smaller than the area of the insulating board 21 and is larger than the area of the region where the plurality of conductive patterns 22 are formed. The corners of the metal plate 23 may be chamfered into rounded or beveled shapes. The metal plate 23 is smaller than the insulating board 21 and is formed across the entire surface of the insulating board 21 except for the edges. The metal plate 23 has a metal with superior thermal conductivity as a main component. Example metals include copper, aluminum, and an alloy containing at least one of these metals, and the surface of the metal plate 23 may be plated. When doing so, examples of the plating material used include nickel, nickel-phosphorus alloy, and nickel-boron alloy. Plating the metal plate 23 improves corrosion resistance.

As examples, a direct copper bonding (DCB) board or an active metal brazed (AMB) board may be used as the insulated circuit board 20 with the configuration described above. A cooler (not illustrated) may be attached to a rear surface of the insulated circuit board 20 (the semiconductor module 1) via a bonding member. By doing so, heat dissipation of the semiconductor module 1 is improved. As examples, the cooler may be made of aluminum, iron, silver, or copper, which have superior thermal conductivity, or an alloy containing at least one of these metals. Example coolers include a heat sink and a cooling device that uses water-cooling. The heat sink may be formed with a plurality of fins. Examples of the bonding member include a brazing material and a thermal interface material (TIM). As examples, the brazing material has at least one of an aluminum alloy, a titanium alloy, a magnesium alloy, a zirconium alloy, or a silicon alloy as a main component. The bonding member may be a thermal interface material. TIM is a general name for materials such as thermally conductive grease, elastomer sheets, room temperature vulcanization (RTV) rubber, gels, and phase change materials.

As one example, the semiconductor chips 30a and 30b may be constructed with silicon as a main component. The semiconductor chip 30a is a switching element. Examples of switching elements include an integrated gate bipolar transistor (IGBT) or a power metal-oxide-semiconductor field-effect transistor (MOSFET). When the semiconductor chip 30a is an IGBT, the semiconductor chip 30a is equipped with a collector electrode as a main electrode on a rear surface, and a gate electrode as a control electrode and an emitter electrode as a main electrode on a front surface. When the semiconductor chip 30a is a power MOSFET, the semiconductor chip 30a has a drain electrode as a main electrode on a rear surface and a gate electrode as a control electrode and a source electrode as a main electrode on a front surface.

The semiconductor chip 30b is a diode element. As examples, this diode element may use a Schottky Barrier diode (SBD) or a P-intrinsic-N (PiN) diode as a freewheeling diode (FWD). The semiconductor chip 30b is equipped with a cathode electrode as a main electrode on a rear surface and an anode electrode as a main electrode on a front surface. The rear surfaces of the semiconductor chips 30a and 30b are bonded by bonding members (not illustrated) to predetermined conductive patterns 22.

Alternatively, in place of the semiconductor chips 30a and 30b, a semiconductor chip including a reverse-conducting (RC)-IGBT made of silicon may be used. An RC-IGBT combines the functions of an IGBT, which is a switching element, and an FWD, which is a diode element. This type of semiconductor chip has a collector electrode as a main electrode on a rear surface, and a gate electrode, which is a control electrode, and an emitter electrode, which is also a main electrode, on a front surface.

Alternatively, in place of the RC-IGBT, a semiconductor chip including a power MOSFET made of silicon carbide may be used. A body diode of a power MOSFET may perform a similar function to the FWD in an RC-IGBT. This type of semiconductor chip is equipped with a collector electrode as a main electrode on a rear surface, and a gate electrode as a control electrode and an emitter electrode as a main electrode on a front surface.

Note that as examples, the bonding members for bonding the semiconductor chips 30a and 30b to the conductive patterns 22 may be solder or sintered material. Lead-free solder is used as the solder. Lead-free solder has at least one of an alloy of tin, silver, and copper, an alloy of tin, zinc, and bismuth, an alloy of tin and copper, or an alloy of tin, silver, indium, and bismuth as a main component. The solder may further contain additives. Example additives include nickel, germanium, cobalt, and silicon. By including additives, it is possible to improve the wettability, gloss, and bonding strength of the solder, which improves reliability. As examples, the sintered material has silver or a silver alloy as a main component.

Note that an electronic component 30c may be disposed on the conductive pattern 22 to enable the semiconductor module 1 to realize a desired function. Depending on this function, the electronic component 30c may be a thermistor or a current sensor, for example. The electronic component 30c may be bonded to a conductive pattern 22 using a bonding member like those described above.

The external connection terminals 32 are electrically connected to the conductive patterns 22 by contact components 31. Each contact component 31 is provided with a main body portion, in which a cylindrical through-hole is formed, and flanges provided at each open end of the main body portion. One open end of each contact component 31 is bonded via a bonding member to a predetermined position on the plurality of conductive patterns 22 provided on the front surface of the insulated circuit board 20. An external connection terminal 32 is press-fitted onto the other open end of each contact component 31. The contact components 31 are made of a metal with superior electrical conductivity. Examples of such metals include copper, aluminum, silver, nickel, or alloys containing at least one of these metals as a main component. To improve corrosion resistance, the surfaces of the contact components 31 may be plated. Examples of the plating material used in this case include nickel, nickel-phosphorus alloy, and nickel-boron alloy.

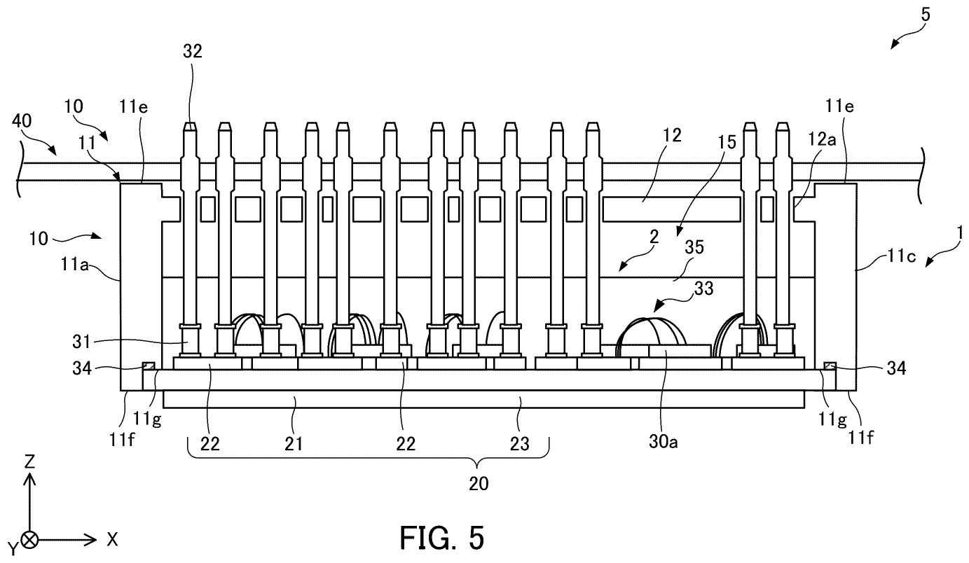

Each external connection terminal 32 is a press-fitted terminal including a main body portion that is rod-shaped, tapered tip portions formed at both ends of the main body portion, and a thickened portion formed at an upper part of the main body portion. The lower tip portion of each external connection terminal 32 is press-fitted into a contact component 31. The upper tip portion is later press-fitted into a printed circuit board 40 (see FIG. 5). The main body portion is shaped as a rectangular column, for example. Each external connection terminal 32 is made of a metal with superior electrical conductivity. Example metals include copper, aluminum, nickel, or an alloy containing at least one of these metals as a main component. Surfaces of the external connection terminals 32 may be plated to improve corrosion resistance. Examples of the plating material used in this case include nickel, nickel-phosphorus alloy, and nickel-boron alloy. Note that the external connection terminals 32 are not limited to press-fitted terminals, and may be terminals whose main body portions are substantially straight without including thickened portions.

The external connection terminals 32 may be bonded to the insulated circuit board 20 without using the contact components 31. As one example, the external connection terminals 32 may be bonded directly to the conductive patterns 22 on the insulated circuit board 20 by ultrasonic bonding or the like. The external connection terminals 32 may be bonded to the conductive patterns 22 of the insulated circuit board 20 via solder or brazing material, for example.

In the semiconductor unit 2, a power converter circuit is constructed by using wires 33 to connect between the semiconductor chips 30a and 30b, between the semiconductor chips 30a and 30b and the conductive patterns 22, and between the plurality of conductive patterns 22. As examples, the wires 33 are made of gold, silver, copper, aluminum, or an alloy containing at least one of these metals as a main component.

The encapsulating member 35 includes a thermosetting resin and a filler contained in the thermosetting resin. As examples, the thermosetting resin is epoxy resin, phenol resin, or maleimide resin. Examples of the filler include silicon oxide, aluminum oxide, boron nitride, and aluminum nitride.

In the semiconductor module 1, the case 10 covers the components disposed on the insulated circuit board 20 and is fixed by an adhesive 34 that has been applied around the outer circumferential edge of the insulated circuit board 20 (the insulating board 21). Note that a step 11g is formed around an opening 11h on the inside of the lower surface 11f of the outer frame 11 of the case 10. This step 11g is L-shaped in cross section. The outer circumferential edge of the insulating board 21 of the insulated circuit board 20 fits into this step 11g, so that the insulated circuit board 20 covers the opening 11h in the housing region 15 of the case 10 (the outer frame 11).

The encapsulating member 35 fills the housing region 15 of the case 10 and encapsulates the front surface of the insulated circuit board 20. That is, the encapsulating member 35 encapsulates the plurality of conductive patterns 22, the semiconductor chips 30a and 30b, the contact components 31, lower parts of the external connection terminals 32, and the wires 33. A gap may be provided between a front surface of the encapsulating member 35 and the lid portion 12.

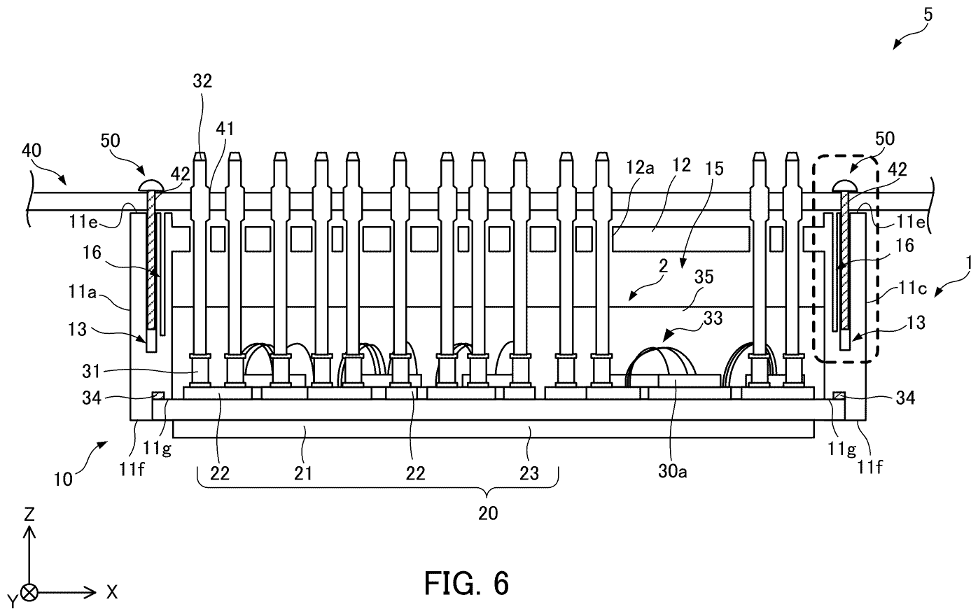

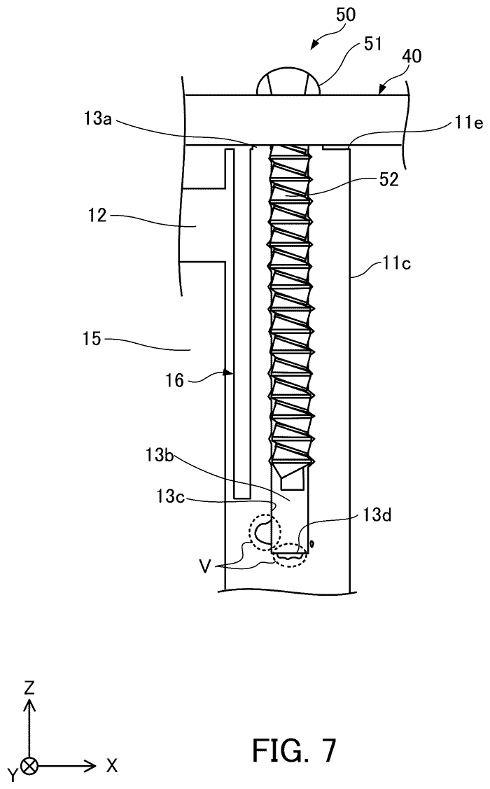

Next, the semiconductor module 1 to which the printed circuit board has been attached will be described with reference to FIGS. 5 to 7. FIG. 5 is a first cross-sectional view of a semiconductor module to which a printed circuit board according to the first embodiment has been attached, and FIG. 6 is a second cross-sectional view of a semiconductor module to which a printed circuit board according to the first embodiment has been attached. FIG. 7 is an enlarged cross-sectional view of a semiconductor module to which a printed circuit board according to the first embodiment has been attached.

Note that a semiconductor device 5 is formed by attaching the printed circuit board 40 to the semiconductor module 1 depicted in FIG. 1. FIGS. 5 and 6 are cross-sectional views of the semiconductor device 5 taken along dash-dotted lines Y1-Y1 and Y2-Y2, respectively, on the semiconductor module 1 depicted in FIG. 1. FIG. 7 is an enlarged view of the area surrounded by a broken line in FIG. 6.

The semiconductor device 5 includes the semiconductor module 1 and the printed circuit board 40. Although not illustrated, the printed circuit board 40 includes an insulating board and a plurality of upper circuit patterns formed on a front surface of the insulating board. As needed, the printed circuit board 40 is also equipped with a plurality of lower circuit patterns on a rear surface of the insulating board. In addition, the printed circuit board 40 has a plurality of through-holes 41, which pass through from the front surface to the rear surface, formed at positions corresponding to the external connection terminals 32 of the semiconductor module 1. The printed circuit board 40 also has alignment holes 42 (see FIG. 6) formed in the four corners of a region where the plurality of through-holes 41 are formed.

The insulating board is shaped as a flat plate and made of an electrically insulating material. The material of the insulating board is produced by soaking a substrate in resin. As examples, the substrate may be paper, glass cloth, or nonwoven glass cloth. As examples, the resin may be phenol resin, epoxy resin, or polyimide resin. A paper phenol board, a paper epoxy board, a glass epoxy board, a glass polyimide board, and a glass composite board may be used as specific examples of the insulating board. Such insulating boards are also rectangular in plan view. The corners of the insulating board may be chamfered into rounded or beveled shapes.

The upper circuit patterns and the lower circuit patterns are provided in a plurality of pattern shapes so as to form a predetermined circuit. The upper circuit patterns and the lower circuit patterns are made of a material with superior electrical conductivity. Example materials include silver, copper, nickel, or an alloy containing at least one of these metals. To improve corrosion resistance, surfaces of the upper circuit patterns and the lower circuit patterns may be plated. Example materials used for this plating include nickel, nickel-phosphorus alloy, and nickel-boron alloy. The through-holes 41 are electrically connected as appropriate to at least one of the upper circuit patterns or the lower circuit patterns.

The external connection terminals 32 of the semiconductor module 1 are press-fitted into the through-holes 41 of the printed circuit board 40. In addition, the printed circuit board 40 is fixed to the semiconductor module 1 with tapping screws 50 that have been inserted through the alignment holes 42. By doing so, the printed circuit board 40 and the semiconductor module 1 are electrically connected. Note that when the external connection terminals 32 are straight terminals instead of press-fitted terminals, the external connection terminals 32 may be inserted into the through-holes 41 and fixed at the through-holes 41 by solder.

When the external connection terminals 32 are press-fitted into the printed circuit board 40, the rear surface of the printed circuit board 40 will contact the upper surface 11e of the case 10 (the outer frame 11). When this happens, the alignment holes 42 of the printed circuit board 40 will be positioned at the fastening portions 13 of the case 10 (the outer frame 11). The tapping screws 50 are then inserted through the alignment holes 42 of the printed circuit board 40 and attached to the case 10 (the outer frame 11).

As described earlier, in plan view, the fastening portions 13 are formed on the upper surface 11e on the side walls 11b and 11d on the sides of the side walls 11a and 11c. Each fastening portion 13 includes a boss portion 13a and a fastening hole 13b formed by a fastening surface 13c and a fastening bottom surface 13d.

The boss portion 13a is formed in a continuous ring shape that surrounds the fastening hole 13b on the upper surface 11e. The fastening hole 13b is tubular. As one example, the fastening hole 13b is shaped as a circular tube and circular in plan view. Each fastening hole 13b is formed longer (deeper) than the tapping screws 50 and extends from the upper surface 11e of the outer frame 11 without reaching the lower surface 11f. Each fastening hole 13b is a region surrounded by the fastening surface 13c and the fastening bottom surface 13d. Each fastening surface 13c is a curved surface that extends within the outer frame 11 from the upper surface 11e toward the lower surface 11f of the outer frame 11. Each fastening surface 13c is substantially smooth before a tapping screw 50 is screwed in. When a tapping screw 50 is screwed in, a spiral groove is formed in the fastening surface 13c by the thread of the tapping screw 50. The fastening bottom surface 13d is connected to the lowest end of the fastening surface 13c. The fastening bottom surface 13d is substantially circular in plan view. Note that voids V are included in inner peripheries of a lower part (in the −Z direction) of the fastening surface 13c and the fastening bottom surface 13d. There are hardly any voids V in an inner vicinity of an upper part (in the +Z direction) of the fastening surface 13c.

Each tapping screw 50 includes a head portion 51 and a threaded portion 52. The head portion 51 is integrally joined to another end of the threaded portion 52. This expression the “other end” of the threaded portion 52 is the end that is opposite the tip portion of the threaded portion 52, which is cylindrical. It is sufficient for a surface of the head portion 51 that is joined to the other end of the threaded portion 52 to be a main surface that is substantially smooth. The head portion 51 itself may be rectangular, hemispherical, or trapezoidal in a side view. The diameter of the head portion 51 is larger than the diameter of the threaded portion 52, and as examples is two or more times greater than but four or less times than the diameter of the threaded portion 52.

The threaded portion 52 is cylindrical and has a reduced diameter at the tip portion (the −Z direction side in FIG. 7). A spiral thread is formed on a side portion (or “main body portion”) of the threaded portion 52 aside from at the tip portion. The diameter of the threaded portion 52 corresponds to the diameter of the fastening hole 13b.

The tapping screws 50 are made of a material that is expected to have high strength. Examples of such materials include steel, stainless steel, brass, aluminum, magnesium, plastic, and titanium. When a tapping screw 50 is inserted through an alignment hole 42 of the printed circuit board 40 and enters a fastening hole 13b of the case 10 (the outer frame 11) while rotating, the thread of the tapping screw 50 will advance in the −Z direction while forming a groove in the fastening surface 13c. In this way, the tapping screws 50 are screwed into the fastening holes 13b.

Each columnar notch 16 is formed parallel to a fastening hole 13b on a housing region 15-side of the fastening hole 13b. The columnar notch 16 is a hole that extends from the upper surface 11e of the outer frame 11 toward the lower surface 11f. Each columnar notch 16 is columnar and longer (deeper) than the tapping screws 50 screwed into the fastening holes 13b. As one example, the columnar notches 16 are shaped as rectangular columns. The length (depth) of the columnar notches 16 from the upper surface 11e to their lower end portions may be shorter (shallower) than the length (depth) from the upper surface 11e to the lower end portion of the fastening holes 13b. The length (depth) from the upper surface 11e to the lower end portions of the columnar notches 16 may be at least 40% of but not greater than 50% of the length (depth) from the upper surface 11e to the lower end portion of the fastening holes 13b.

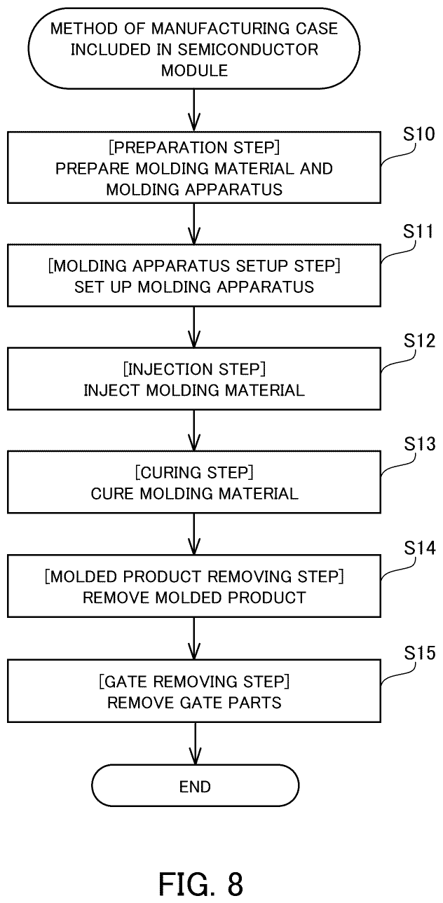

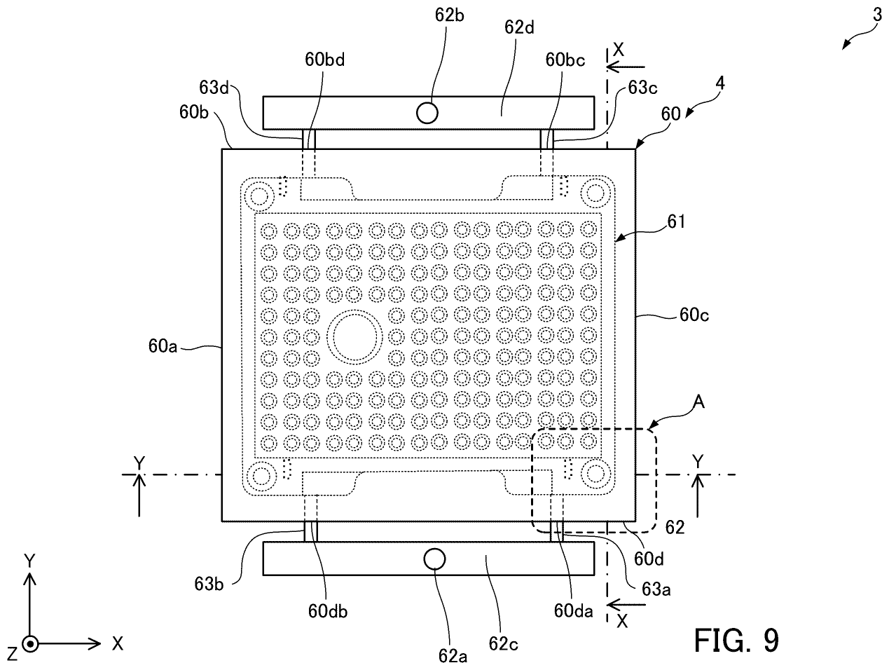

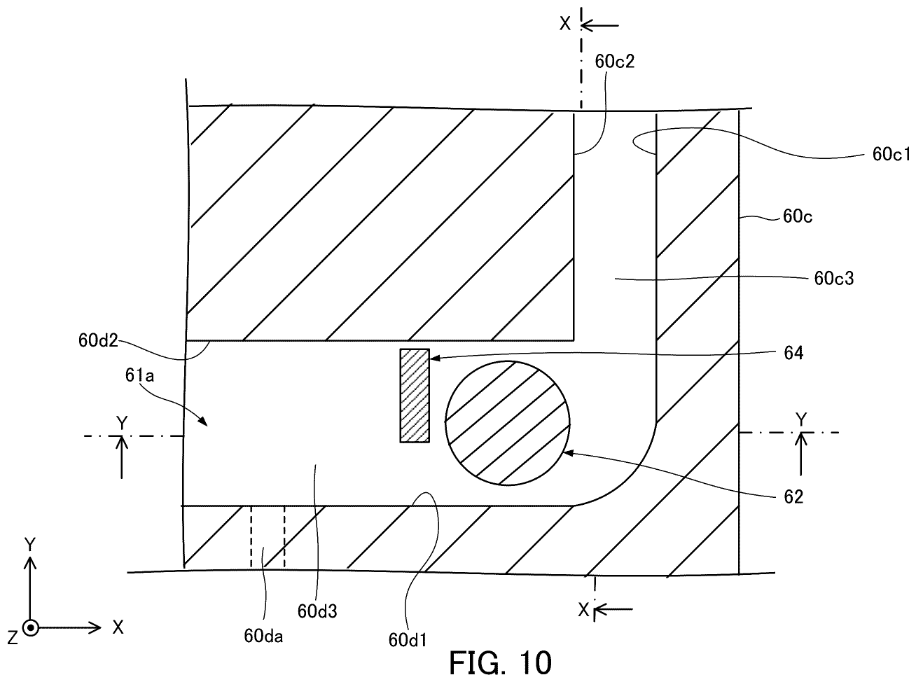

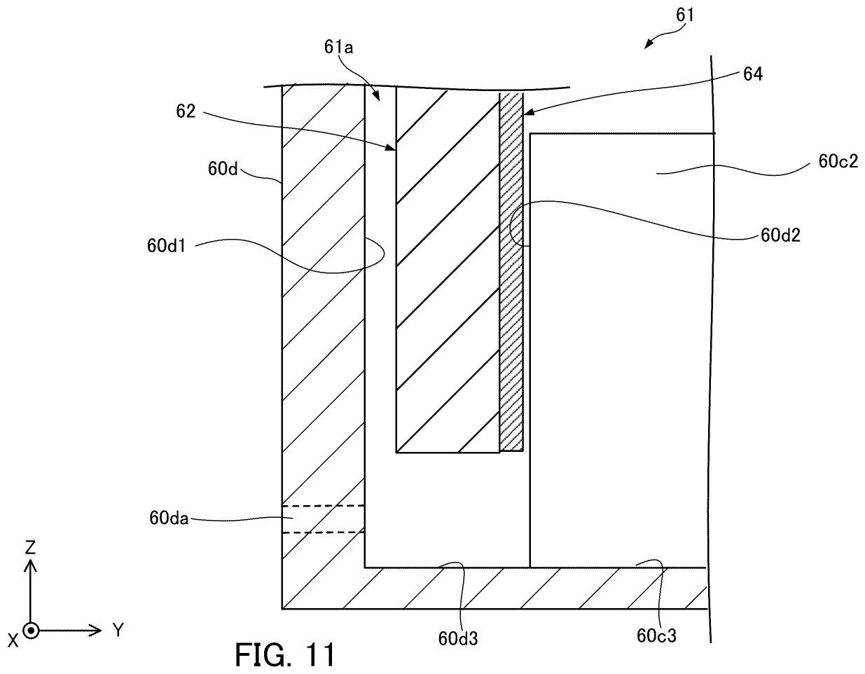

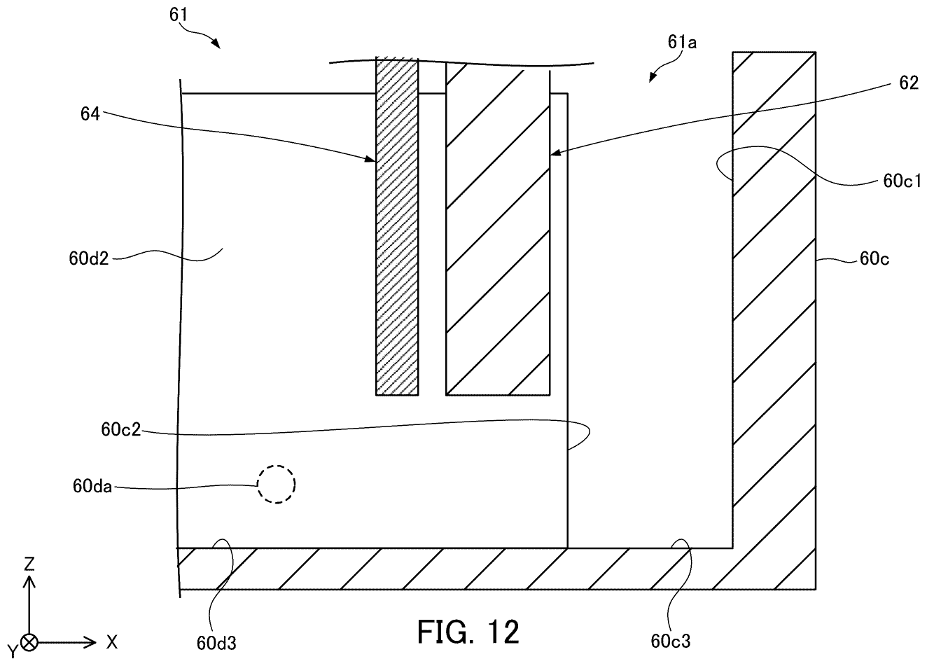

Next, a method of manufacturing the case 10 included in the method of manufacturing the semiconductor module 1 described above will be described with reference to FIGS. 8 to 12. FIG. 8 is a flowchart depicting a method of manufacturing the case included in the semiconductor module according to the first embodiment. FIG. 9 is a plan view of a molding apparatus according to the first embodiment. FIG. 10 is a first cross-sectional view of a molding die included in the molding apparatus according to the first embodiment, FIG. 11 is a second cross-sectional view of the molding die included in the molding apparatus according to the first embodiment, and FIG. 12 is a third cross-sectional view of the molding die included in the molding apparatus according to the first embodiment. Note that although a range A in FIG. 9 is described below, the same applies to similar ranges in the other three corners of the outer frame 11 in FIG. 9. FIG. 10 depicts a cross-sectional view, taken parallel to the X-Y plane, of the range A in a corner of the outer frame 11 surrounded by a broken line in FIG. 9. FIG. 11 is a cross-sectional view taken along a dash-dotted line X-X in FIG. 9. FIG. 12 depicts a cross-sectional view taken along a dash-dotted line Y-Y in FIG. 9.

First, a preparation step that prepares items used to manufacture the case 10 is performed (step S10). As examples, the items prepared here include a molding material used for the outer frame 11, metal fittings that form the mounting portions 14, and a molding apparatus, described later. It is also possible to prepare items aside from those listed here as needed.

Next, a molding apparatus setup step is performed to set up the molding apparatus (step S11). As depicted in FIG. 9, the molding apparatus 3 to be set up includes at least the molding die 4, sprues 62a and 62b, runners 62c and 62d, or gates 63a to 63d.

The molding die 4 includes a first die component 60 and second die components 64. The first die component 60 is box-shaped and has a cavity 61 formed inside. The first die component 60 includes side surfaces 60a to 60d that surround the four sides in that order in plan view. Note that the side surfaces 60b and 60d correspond to the side walls 11b and 11d of the outer frame 11 which is to be molded inside the cavity 61. The side surfaces 60a and 60c correspond respectively to the side walls 11a and 11c of the outer frame 11 to be molded inside the cavity 61. Injection ports 60bd and 60bc and injection ports 60db and 60da, which communicate with the cavity 61, are formed in the side surfaces 60b and 60d, respectively.

The injection ports 60bd and 60bc and the injection ports 60db and 60da are positioned on the side surfaces 60b and 60d a predetermined distance inward (that is, in the +X direction) from the side surfaces 60a and 60c in plan view. In a side view, the injection ports 60bd and 60bc and the injection ports 60db and 60da are positioned in a vicinity of the bottom surfaces of the side surfaces 60b and 60d. In other words, the injection ports 60bd and 60bc and the injection ports 60db and 60da are provided at positions on the side surfaces 60b and 60d which, in plan view, correspond to the outermost surfaces 11b1 and 11b5 and the outermost surfaces 11d1 and 11d5 of the fastening parts of the outer frame 11 and also to the upper surface 11e to which the inclined surfaces 11d2 and 11d4 and the inclined surfaces 11b2 and 11b4 are connected.

The cavity 61 in the first die component 60 includes a molding space 61a in which the outer frame 11 is molded. As depicted in FIGS. 10 to 12, this molding space 61a includes molding inner surfaces 60d2 and 60c2 that define the outer frame 11 and the housing region 15 of the outer frame 11, molding outer surfaces 60d1 and 60c1 that are provided outside the molding inner surfaces 60d2 and 60c2 and contact the side walls 11d and 11c of the outer frame 11, and molding bottom surfaces 60d3 and 60c3 that connect the molding inner surfaces 60d2 and 60c2 and the molding outer surfaces 60d1 and 60c1 and contact the lower surface 11f of the outer frame 11. Note that the widths of the molding bottom surfaces 60d3 and 60c3 correspond to the thicknesses of the side walls 11d and 11c of the outer frame 11. In the molding outer surface 60d1, in plan view, the injection port 60da that communicates with the molding space 61a is formed so as to be inwardly separated (in the −X direction) from an end portion (on the +X direction side) of the molding outer surface 60d1.

In addition, the first die component 60 includes mold pin portions (mold pins) 62. The mold pin portions 62 are rod-shaped and correspond to the fastening holes 13b included in the outer frame 11. In plan view, the mold pin portions 62 are disposed perpendicularly to the molding bottom surface 60d3 at corners of the molding space 61a. The mold pin portions 62 may be integrally formed with the first die component 60.

Each second die component 64 is rod shaped and corresponds to a columnar notch 16 included in the outer frame 11. Here, as one example, the second die components 64 are column shaped and rectangular in plan view. The illustrated second die component 64 is disposed parallel to the mold pin portions 62 at a location in the molding space 61a which, in plan view, is between the mold pin portions 62 and the injection port 60da and is closer to the molding inner surface 60d2 than the molding outer surface 60d1. That is, although the second die component 64 is disposed so as to cover a gap between the molding inner surface 60d2 and the mold pin portions 62 on the injection port 60da side, such gap is not completely closed. It is preferable for the second die component 64 to be separated from the mold pin portion 62 on the injection port 60da (−X direction) side by 1 mm or more in plan view. Since the second die components 64 correspond to the columnar notches 16 included in the outer frame 11, second die components 64 have the same length as the columnar notches 16. In other words, the length to the bottom end portions of the second die components 64 inside the molding space 61a may be at least 40% but not greater than 50% of the length to the bottom end portions of the mold pin portions 62 inside the molding space 61a. Note that a configuration where the second die components 64 and the mold pin portions 62 have the same length is illustrated here.

The filled molding material passes through the sprues 62a and 62b and flows into the runners 62c and 62d. The runners 62c and 62d enable the molding material that has flowed in from the sprues 62a and 62b to flow into the gates 63a and 63b and the gates 63c and 63d. The gates 63a and 63b and the gates 63c and 63d are connected to the injection ports 60da and 60db and the injection ports 60bc and 60bd, respectively. The gates 63a and 63b and gates 63c and 63d enable the molding material that has flowed in from the runners 62c and 62d to fill the cavity 61 of the first die component 60 through the injection ports 60da and 60db and the injection ports 60bc and 60bd.

Metal fittings that will become the mounting portions 14 are set in predetermined locations inside the cavity 61 of this molding die 4.

Next, an injection step is performed where molding material is injected into the cavity 61 of the molding die 4 (step S12). With the molding die 4 maintained at a predetermined temperature, the molten molding material flows from the sprues 62a and 62b of the molding apparatus 3 so that the molding material is injected into the cavity 61 (that is, the molding space 61a) of the molding die 4. The flow of the molding material inside the cavity 61 of the molding die 4 at this time will be described later.

Next, a curing step in which the molding material injected inside the cavity 61 of the molding die 4 is cured is performed (step S13). The molding die 4 whose cavity 61 has been filled with the molding material is cooled to a predetermined temperature and this temperature is then maintained for a certain time.

Next, a molded product removing step is performed to remove a molded product from the molding die 4 (step S14). The molding die 4 is opened and the molded product in the molding die 4 is ejected by using ejection pins to eject the molded product. When the molding die 4 is released, the mold pin portions 62 and the second die components 64 are withdrawn from the molded product resulting in the formation of the fastening holes 13b and the columnar notches 16.

Next, a gate removing step is performed (step S15) to remove the parts corresponding to the gates 63a to 63d from the molded product that was removed in step S14. Parts corresponding to the gates 63a to 63d remain connected to the molded product that was removed in step S14. By removing these parts, the case 10 is obtained. Gate marks S on the side walls 11b and 11d of the case 10 are locations where parts corresponding to gates 63a to 63d were connected. Note that the parts corresponding to the gates 63a to 63d may be removed by breaking them off, for example. Alternatively, when the parts corresponding to gates 63a to 63d are too thick to bend, the parts may be cut off with a cutter, for example.

On the other hand, the semiconductor chips 30a and 30b and the contact components 31 are bonded to predetermined conductive patterns 22 of the insulated circuit board 20 by bonding members. Wiring is performed using the wires 33. The external connection terminals 32 are press-fitted into components 31. The contact semiconductor unit 2 formed in this way is attached from the opening 11h in the lower surface 11f of the case 10. At this time, the external connection terminals 32 are inserted through the terminal holes 12a in the lid portion 12 of the case 10. Also, at this time, the outer edge of the insulated circuit board 20 is fixed to the step 11g of the case 10 via the adhesive 34 that has been applied to the outer edge. The housing region 15 inside the case 10 is filled with the encapsulating member 35 to encapsulate the components on the front surface of the insulated circuit board 20. Through the steps described above, the semiconductor module 1 is obtained.

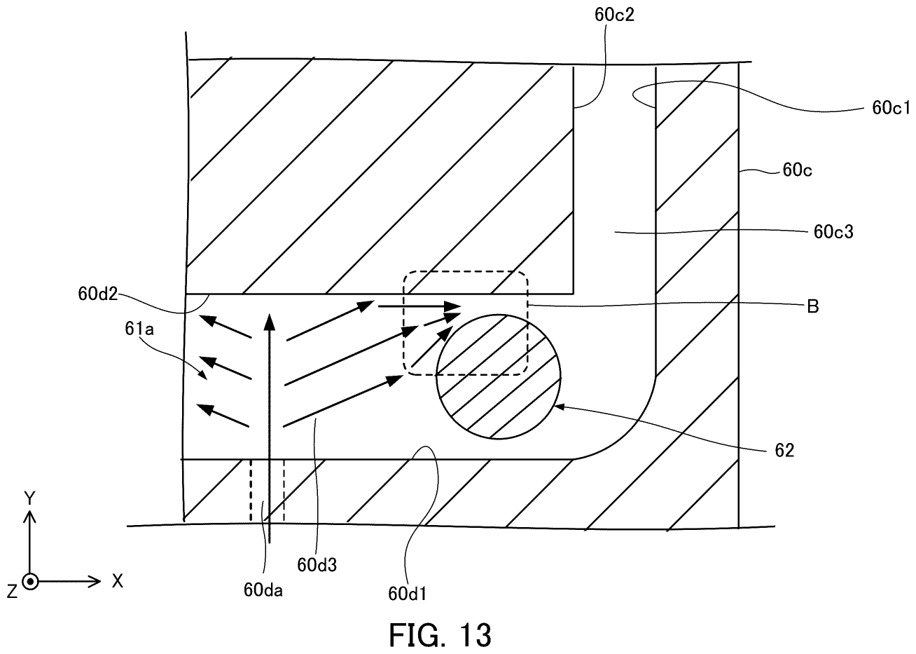

Here, a comparative example for the method of manufacturing the case 10 (the outer frame 11) according to the first embodiment will be described. In this comparative example, the case 10 is manufactured using the molding die 4 according to the first embodiment without using the second die components 64. In other words, the case 10 used as a comparative example is manufactured using only the first die component 60. This case 10 according to the comparative example is also manufactured according to the flowchart in FIG. 8. The flow of the molding material when only the first die component 60 is used in the injection step in step S12 will now be described with reference to FIG. 13. FIG. 13 is a first cross-sectional view depicting the injection step included in the method of manufacturing of a case according to this comparative example. Note that the solid arrows in FIG. 13 indicate flows of the molding material. FIG. 13 corresponds to FIG. 10, but with the second die component 64 omitted from FIG. 10.

The molding material that has flowed in from the sprue 62a passes through the runner 62c and the gate 63a, and is injected into the molding space 61a from the injection port 60da in the side surface 60d of the first die component 60. The molding material injected into the molding space 61a spreads out inside the molding space 61a. The molding material flows from a region surrounded by the molding inner surface 60d2, the molding outer surface 60d1, and the molding bottom surface 60d3 into a region surrounded by the molding inner surface 60c2, the molding outer surface 60c1, and the molding bottom surface 60c3. When doing so, the molding material flows through a gap B (the region surrounded by the broken line) between a mold pin portion 62 and the molding inner surface 60d2.

When the molding material has flowed into the gap B, which is sufficiently narrower than other locations, the flow rate at the gap B will decrease. As a result, the flow of the molding material in the periphery of a mold pin portion 62 will be poor and the material will tend to stagnate more than at other locations. Accordingly, the molding material is more likely to shrink in the periphery of a mold pin portion 62.

In this state, when the molding material starts to cure in the curing step of step S13, the molding material at the gap B will be the last to cure, resulting in voids being generated and included at the gap B. Following this, the case 10 is obtained via steps S14 and S15.

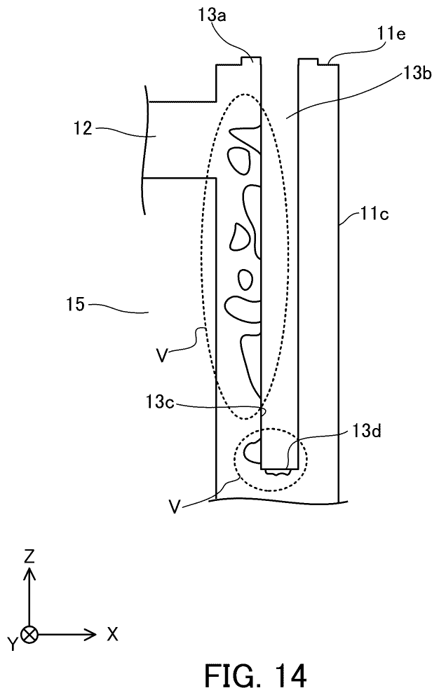

Next, the fastening holes 13b in the case 10 (the outer frame 11) manufactured in this way will be described with reference to FIG. 14. FIG. 14 is an enlarged cross-sectional view of a case according to a comparative example. Note that FIG. 14 corresponds to a state before the tapping screw 50 in FIG. 7 is attached.

With the case 10 manufactured using the molding die 4 of the comparative example, many out of the plurality of voids V are included in the inner periphery of the fastening surface 13c of the fastening hole 13b on the side of the housing region 15. In this case, a plurality of voids V are present on the fastening surface 13c in the entire range along the #Z direction. In the same way, voids V are also present in the inner periphery of the fastening bottom surface 13d of the fastening hole 13b.

A tapping screw 50 is screwed into the fastening hole 13b that has voids V present in the inner periphery of the fastening surface 13c as described above. When the tapping screw 50 is screwed into the fastening surface 13c, a spiral groove is formed by the thread of the tapping screw 50. However, a fastening surface 13c that includes the voids V will have a low strength and a groove will not be properly formed. Accordingly, the tapping screw 50 fails to be securely screwed into the fastening hole 13b. The tapping screw 50 may spin freely in the fastening hole 13b or fall out of the fastening hole 13b. As a result, the printed circuit board 40 fails to be securely fixed to the semiconductor module 1.

On the other hand, the molding die 4 according to the first embodiment includes a second die components 64 in addition to the first die component 60. During the injection step (step S12), the rod-shaped second die component 64 is positioned parallel to the mold pin portions 62 at a location in the molding space 61a which, in plan view, is between the mold pin portions 62 and the injection port 60da and is closer to the molding inner surface 60d2 than the molding outer surface 60d1. That is, the second die component 64 is positioned parallel to the mold pin portion 62 in the gap between the mold pin portions 62 and the molding inner surface 60d2 on the injection port 60da side. The molding material injected into the molding space 61a flows toward the gap B between a mold pin portion 62 and the molding inner surface 60d2 (see FIG. 13). When this happens, in plan view, the molding material flows around the second die component 64 and into the gap B between the mold pin portion 62 and the molding inner surface 60d2. In other words, the second die component 64 prevents the molding material from stagnating around the mold pin portion 62, which reduces shrinkage of the molding material around the mold pin portion 62. The generation of voids is reduced even when the molding material cures in this state in the curing step in step S13. The outer frame 11 manufactured in this way contains hardly any voids V inside the fastening surface 13c of the fastening hole 13b. This means that when a tapping screw 50 is screwed into a fastening hole 13b, a groove is reliably formed on the fastening surface 13c by the thread of the tapping screw 50, which means that the tapping screw 50 becomes securely fastened to the fastening hole 13b without spinning freely or coming loose. In this way, with the semiconductor device 5, the printed circuit board 40 is securely attached to the semiconductor module 1.

To reliably fasten the tapping screw 50 to the fastening hole 13b, it is sufficient for voids V to not be included in at least an upper part of the fastening surface 13c. In more detail, when a tapping screw 50 is screwed into the fastening hole 13b as depicted in FIG. 7, it is preferable for no voids V to be included between the upper surface 11e of the fastening surface 13c and a position approximately halfway along the tapping screw 50. For this reason, the length (depth) from the upper surface 11e to the lower end portion of each columnar notch 16 may be at least 40% but not greater than 50% of the length (depth) from the upper surface 11e to the lower end portion of the fastening hole 13b. In other words, the length to the lower end portion of the second die components 64 in the molding space 61a may also be at least 40% but not greater than 50% of the length inside the molding space 61a to the lower end portion of the mold pin portion 62.

### Second Embodiment

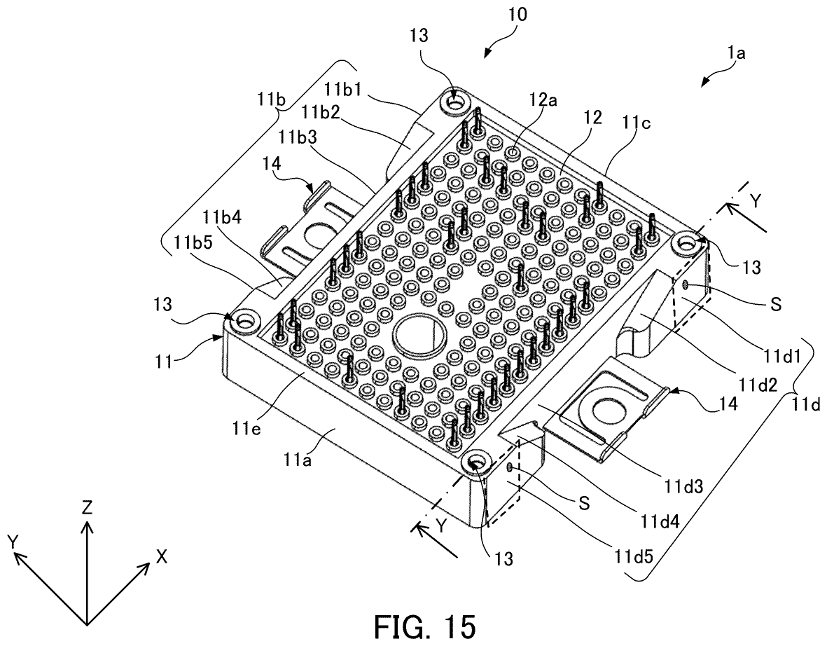

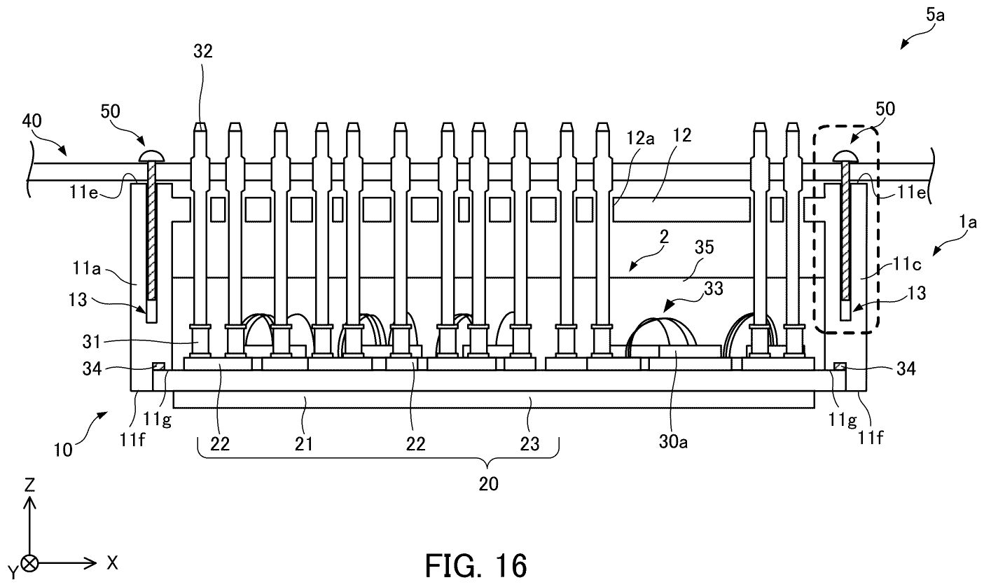

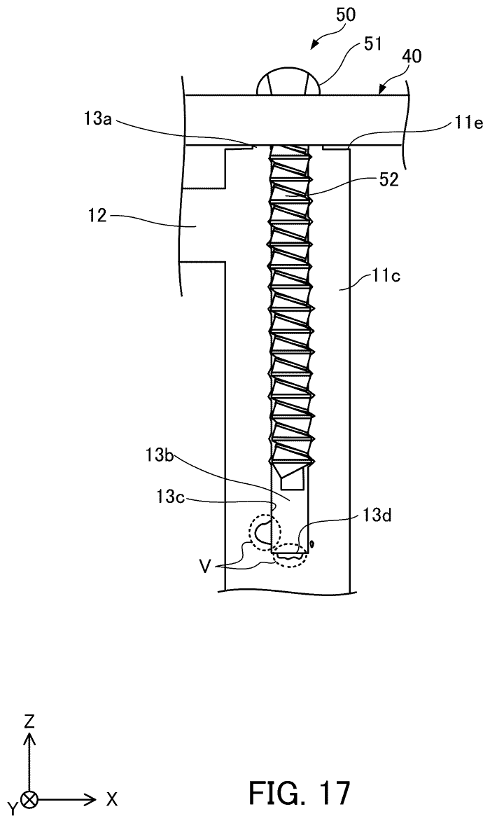

In a second embodiment, the molding die 4 according to the first embodiment is used to manufacture a case 10 (an outer frame 11) including fastening holes 13b with fewer voids without using second die components. First, a semiconductor module and a semiconductor device according to the second embodiment will be described with reference to FIGS. 15 to 17. FIG. 15 is a perspective view of a semiconductor module according to the second embodiment. FIG. 16 is a second cross-sectional view of a semiconductor module to which a printed circuit board according to the second embodiment has been attached. FIG. 17 is an enlarged cross-sectional view of a semiconductor module to which the printed circuit board according to a second embodiment has been attached.

In the same way as in the first embodiment, the semiconductor module 1a includes a case 10 and semiconductor unit 2 housed inside the case 10. A plurality of external connection terminals 32 included in the semiconductor unit 2 extend outside from the front surface of the case 10. The inside of the case 10 is encapsulated with an encapsulating member 35.

In the semiconductor device 5a, a printed circuit board 40 is attached to the semiconductor module 1a by tapping screws 50. The tapping screws 50 are inserted through through-holes 41 in the printed circuit board 40 and securely screwed into fastening holes 13b of the case 10.

However, unlike the first embodiment, the case 10 does not include the columnar notches 16. The positions of the gate marks S on the side walls 11b and 11d of the case 10 are also closer to the upper surface 11e than in the first embodiment.

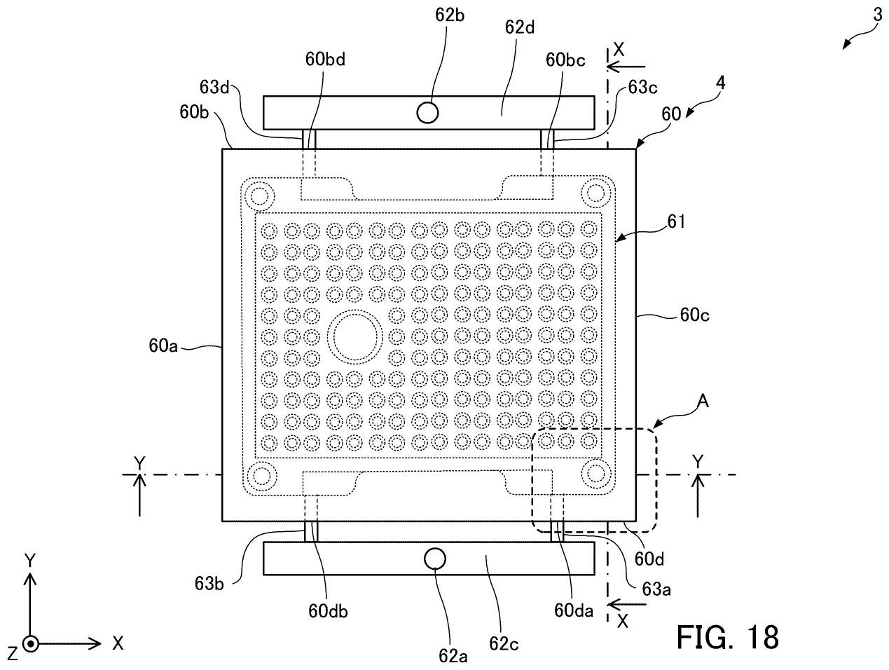

The case 10 according to the second embodiment is also manufactured in accordance with the flowchart in FIG. 8. The molding apparatus 3 used to manufacture the case 10 according to the second embodiment will now be described with reference to FIGS. 18 to 20.

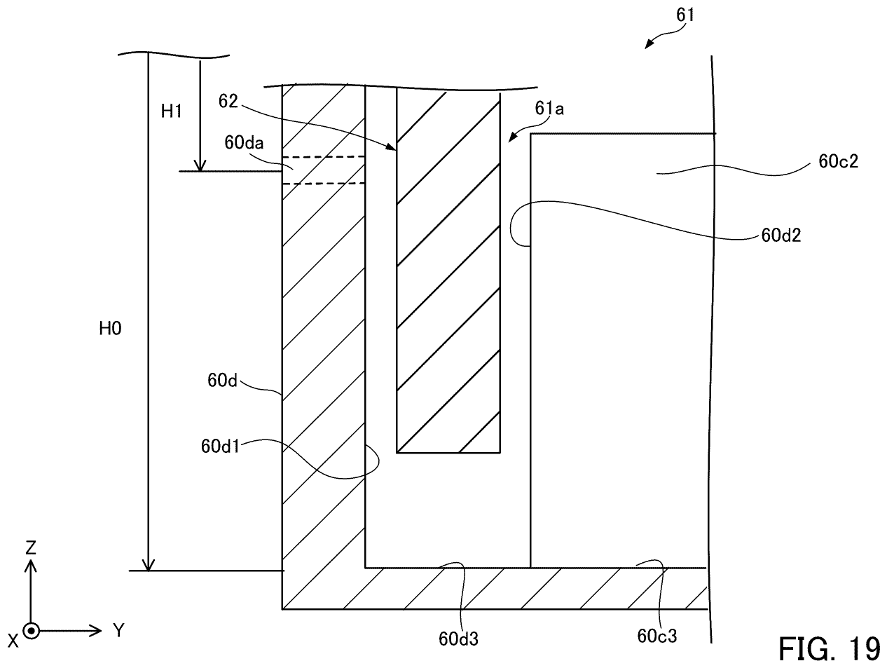

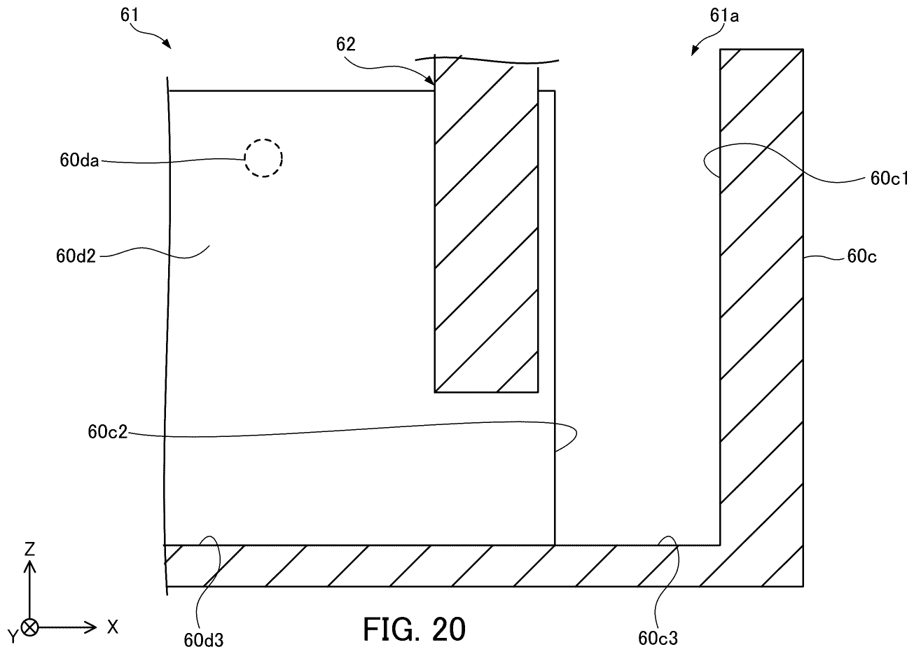

FIG. 18 is a plan view of a molding apparatus according to the second embodiment. FIG. 19 is a second cross-sectional view of a molding die included in the molding apparatus according to the second embodiment, and FIG. 20 is a third cross-sectional view of the molding die included in the molding apparatus according to the second embodiment. Note that although the following description focuses on a range A in FIG. 18, the same applies to similar ranges in the other three corners of the outer frame 11 in FIG. 18. FIGS. 18 to 20 correspond to FIGS. 9, 11, and 12, respectively. FIGS. 19 and 20 are cross-sectional views taken along dash-dotted lines X-X and Y-Y in FIG. 18.

As depicted in FIG. 18, the molding apparatus 3 according to the second embodiment includes at least the molding die 4, the sprues 62a and 62b, the runners 62c and 62d, or the gates 63a to 63d.

The molding die 4 according to the second embodiment includes only the first die component 60. The first die component 60 has a similar configuration as in the first embodiment. However, the injection port 60da is provided at a higher position (in the +Z direction) than in the first embodiment. As one example, as depicted in FIG. 19, the injection port 60da is formed in the molding outer surface 60d1 at a position corresponding to a height H1 from the upper surface 11e of the outer frame 11, which is not greater than 30% of the height H0 from the upper surface 11e to the lower surface 11f.

Since the injection port 60da is formed at an upper part (in the +Z direction) of the molding outer surface 60d1, a drop in the speed at which the molding material flows at an upper part (in the +Z direction) of the mold pin portion 62 is suppressed. As a result, stagnation of the molding material at an upper part (in the +Z direction) of the mold pin portion 62 is reduced, which reduces shrinkage of the molding material. Even when the molding material in this state cures during the curing step in step S13, the generation of voids V in the periphery of the upper part (in the +Z direction) of the mold pin portion 62 is reduced.

As described earlier, for the tapping screw 50 to be securely fastened into the fastening hole 13b, it is sufficient for no voids V to be included in at least an upper part of the fastening surface 13c. Accordingly, by forming the injection port 60da in an upper part (in the +Z direction) of the molding outer surface 60d1, the generation of voids V in the periphery of the upper part (in the +Z direction) of the mold pin portion 62 is reduced. That is, there are hardly any voids V in the periphery of an upper part (in the +Z direction) of the fastening hole 13b of the case 10. For this reason, when a tapping screw 50 is screwed into the fastening hole 13b, a groove is reliably formed in the fastening surface 13c by the thread of the tapping screw 50, so that the tapping screw 50 is securely fastened to the fastening hole 13b without spinning freely or coming loose. This means that with the semiconductor device 5a, the printed circuit board 40 is reliably attached to the semiconductor module 1a.

According to the present disclosure, it is possible to provide a method of manufacturing a semiconductor module capable of securely fastening screws to a case and preventing the screws from coming out during operation, which improves reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A method of manufacturing a semiconductor module, comprising:
preparing a molding material and a molding die, the molding die including a first die component having a cavity corresponding to a shape of an exterior of a case and injection ports that communicate with the cavity from outside the first die component, the molding die further including rod-shaped mold pins for forming tubular fastening holes in the case, into which screws are to be fastened, the case being rectangular in a plan view of the semiconductor module, and having an outer frame that surrounds a housing region within the case, the fastening holes being disposed at respective corners of an upper surface of the outer frame;
providing the mold pins inside the cavity of the first die component and injecting the molding material from the injection ports into the cavity,
wherein the cavity of the first die component has a molding space for molding the outer frame,
the molding space includes:
a molding inner surface defining a boundary of the outer frame and the housing region;
a molding outer surface provided outside the molding inner surface, the molding outer surface having the injection ports that communicate with the molding space, at positions away from a periphery of the molding outer surface; and
a molding bottom surface connecting the molding inner surface to the molding outer surface so as to contact a lower surface of the outer frame,
the mold pins are disposed vertically with respect to the molding bottom surface at respective corners of the molding space in the plan view, and
the molding die further includes rod-shaped second die components, each second die component being disposed, during the injecting of the molding material, between one mold pin and one injection port that are adjacent to each other, so as to be parallel with the one mold pin and positioned closer to the molding inner surface than to the molding outer surface.

2. The method according to claim 1,
wherein in their extending directions, a length of each second die component is at least 40% but not greater than 50% of a length of each mold pin.

3. The method according to claim 1,
wherein the one mold pin and the one injection port that are adjacent to each other are separated by 1 mm or more in a direction parallel to the molding bottom surface.

4. The method according to claim 1,
wherein each second die component is formed in a rectangular column shape in the plan view.

5. The method according to claim 1,
wherein the injecting of the molding material includes injecting the molding material from each of the injection ports to surround the second die components inside the molding space in the plan view, whereby the molding material flows between the mold pins and the molding inner surface.

6. The method according to claim 1,
wherein the outer frame includes a first side wall, a second side wall, a third side wall, and a fourth side wall that respectively face four sides of the housing region, the first side wall and the third side wall extending in a length direction, and
each of the injection ports is formed in an area of the molding outer surface where either the first side wall or the third side wall is molded.

7. The method according to claim 6,
wherein in the plan view, a thickness of each of the first side wall and the third side wall of the outer frame is greater than a thickness of each of the second side wall and the fourth side wall, and
in the plan view, a width of the molding space in an area where either the first side wall or the third side wall is molded is greater than a width of the molding space in an area where either the second side wall or the fourth side wall is molded.

8. The method according to claim 7,
wherein each of the first side wall and the third side wall includes a thicker portion that has one of the fastening holes and is thicker than the remaining portion of a corresponding one of the first side wall and the third side wall, and
each injection port is formed in an area of the molding outer surface where the thicker portion of either the first side wall or the third side wall is molded.

9. The method according to claim 8,
wherein each of the thicker portions has
an upper surface where the one of the fastening holes is formed and a lower surface, and
an inclined surface that is integrally connected to the upper surface and inclined along either the first side wall or the third side wall toward the lower surface as a distance from the one of the fastening holes increases, and
each injection port is formed in an area of the molding outer surface where the thicker portion of either the first side wall or the third side wall is molded.

10. A method of manufacturing a semiconductor module, comprising:
preparing a molding material and a molding die, the molding die including a first die component having a cavity corresponding to a shape of an exterior of a case and injection ports that communicate with the cavity from outside the first die component, the molding die further including rod-shaped mold pins for forming tubular fastening holes in the case, into which screws are to be fastened, the case being rectangular in a plan view of the semiconductor module, and having an outer frame that surrounds a housing region within the case, the fastening holes being disposed at respective corners of an upper surface of the outer frame;
providing the mold pins inside the cavity of the first die component and injecting the molding material from the injection ports into the cavity,
wherein the cavity of the first die component has a molding space for molding the outer frame,
the molding space includes:
a molding inner surface defining a boundary of the outer frame and the housing region;
a molding outer surface provided outside the molding inner surface, the molding outer surface having the injection ports that communicate with the molding space, at positions away from a periphery of the molding outer surface; and
a molding bottom surface connecting the molding inner surface to the molding outer surface so as to contact a lower surface of the outer frame,
the mold pins are disposed vertically with respect to the molding bottom surface at respective corners of the molding space in the plan view, and
the injection ports are formed in the molding outer surface at positions such that, in a vertical direction, a distance from the upper surface of the outer frame does not exceed 30% of a length of the outer frame.

11. The method according to claim 10,
wherein the outer frame includes a first side wall, a second side wall, a third side wall, and a fourth side wall that respectively face four sides of the housing region, the first side wall and the third side wall extending in a length direction, and
each of the injection ports is formed in an area of the molding outer surface where either the first side wall or the third side wall is molded.

12. The method according to claim 11,
wherein in the plan view, a thickness of each of the first side wall and the third side wall of the outer frame is greater than a thickness of each of the second side wall and the fourth side wall, and
in the plan view, a width of the molding space in an area where either the first side wall or the third side wall is molded is greater than a width of the molding space in an area where either the second side wall or the fourth side wall is molded.

13. The method according to claim 12,
wherein each of the first side wall and the third side wall includes a thicker portion that has one of the fastening holes and is thicker than the remaining portion of a corresponding one of the first side wall and the third side wall, and
each injection port is formed in an area of the molding outer surface where the thicker portion of either the first side wall or the third side wall is molded.

14. The method according to claim 13,
wherein each of the thicker portions has
an upper surface where the one of the fastening holes is formed and a lower surface, and
an inclined surface that is integrally connected to the upper surface and inclined along either the first side wall or the third side wall toward the lower surface as a distance from the one of the fastening holes increases, and
each injection port is formed in an area of the molding outer surface where the thicker portion of either the first side wall or the third side wall is molded.
